(19) United States
(12) Patent Application Publication
(10) Pub. No.: US 2011/0046905 A1
(43) Pub. Date: Feb. 24, 2011

(54) BATTERY MANAGEMENT SYSTEM

(76) Inventor: Ross Blade, Victoria (AU)

Correspondence Address: Jackson Walker LLP, 112 E. Pecan, Suite 2400, San Antonio, TX, 78205, US

(21) Appl. No.: 12/811,749

(22) PCT Filed: Dec. 24, 2008
(86) PCT No.: PCT/AU08/01918

§ 371 Date: Aug. 25, 2010

(30) Foreign Application Priority Data
Jan. 6, 2008 (AU) 2008900100
Oct. 24, 2008 (AU) 2008905536

(51) Int. Cl. G01R 31/36

(52) U.S. Cl. 702/63

(57) ABSTRACT

A battery management system for monitoring a plurality of battery cells, including a plurality of electronic boards, each of the electronic boards being mounted on a respective one of the battery cells, wherein the electronic boards are connected in series to a central processor by a twisted wire pair, the twisted wire pair being connected to each electronic board by a coupling, wherein the coupling is open during normal use and is closed to connect the wires of the twisted wire pair in response to sensing a predetermined event in relation to the respective battery cell such that the central processor is able to determine from a level of voltage returned through the twisted wire pair the number of battery cells at which the predetermined event has been sensed.

### FIELD OF THE INVENTION

This invention relates to a battery management system and, more particularly but not exclusively, to a twisted and normally unconnected paired wire based battery management system for the safe use of large lithium-ion rechargeable batteries.

### BACKGROUND OF THE INVENTION

Lithium-ion batteries must be closely monitored for safety and longer life. Electric vehicle (EV) enthusiasts are now turning to large lithium-ion cells as an alternative to the traditional lead acid battery to power their electric vehicles. However, not expert in lithium-ion battery management systems (BMS), they require safe, flexible and easy to install BMS equipment when working with lithium-ion cells.

Present battery management systems offer either multiple-wire or single wire installation options—both with inherent problems. Multi wired systems require the installer to attach two wires to each battery from a central control box. With battery sets comprising as many as 50 cells this means patching as many as 100 wires. It only requires one faulty solder or fitting to render such a BMS ineffective. In addition, it is difficult to secure so many wires so as to prevent an electro magnetic created pulse when these wires vibrate near high current battery connectors while under load—such pulses can and do create false alarms.

While the single wire BMS was designed to overcome the problem of overly complex installation as outlined above it also to fails to simplify the prevention of electro magnetic pulses in vibrating wires. Single wire systems require an electronic board to be mounted on top of each cell. These boards are them connected in series by a single wire from and back to the main control box. Preventing an electro magnetically created pulse is typically done by twisting a pair of wires in the same circuit—this is not directly possible with a single wire BMS.

If however the installer chooses to thread a long return wire, as is sometimes done, the task typically involves manually twisting a single length as long as three metres to four in around the wires that connect each BMS board together. This is a cumbersome task and is generally not as effective properly as using pre formed twisted pair wire.

Examples of the invention seek to provide an improved battery management system which overcomes or at least alleviates one or more disadvantages of previous battery management systems.

### SUMMARY OF THE INVENTION

In accordance with one aspect of the present invention, there is provided a battery management system for monitoring a plurality of battery cells, including a plurality of electronic boards, each of the electronic boards being mounted on a respective one of the battery cells, wherein the electronic boards are connected in series to a central processor by a twisted wire pair, the twisted wire pair being connected to each electronic board by a coupling, wherein the coupling is open during normal use and is closed to connect the wires of the twisted wire pair in response to sensing a predetermined event in relation to the respective battery cell such that the central processor is able to determine from a level of voltage returned through the twisted wire pair the number of battery cells at which the predetermined event has been sensed.

Preferably, each section of the twisted wire pair between successive electronic boards is substantially the same in length.

Preferably, the coupling is a photo-coupler, and each board has a microprocessor for monitoring the respective battery cell, the microprocessor being adapted to operate such that, if a predetermined event occurs, the microprocessor switches on the photo-coupler to connect the wires of the twisted wire pair to allow a current to pass back to the central processor.

It is preferred that the twisted wire pair is prefabricated twisted wire pair.

In a preferred example, the central processor determines the number of battery cells at which the predetermined event has been sensed by multiplying current along the twisted wire pair by a resistance associated with each battery cell, and by dividing that product by the voltage drop along the twisted wire pair. More preferably, each electronic board has a resistor of a known resistance mounted thereon. Even more preferably, each resistor has the same resistance.

Preferably, the predetermined event sensed by the electronic board is a failure of the respective battery cell.

### BRIEF DESCRIPTION OF THE DRAWINGS

The invention is described, by way of non-limiting example only, with reference to the accompanying drawings in which:

FIG. 1 shows a pair of electronic boards connected in a battery management system;

FIG. 2 shows a box containing a central processor of the battery management system;

FIG. 3 shows an electronic board used in a battery management system in accordance with an alternative example; and

FIG. 4 shows a twisted wire pair incorporating a third wire.

### DETAILED DESCRIPTION

The drawings show an example of a battery management system 10 for monitoring a plurality of battery cells 12. The battery management system 10 includes a plurality of electronic boards 14, each of the electronic boards 14 being mounted on a respective one of the battery cells 12. The electronic boards 14 are connected in series to a central processor 16 by a prefabricated twisted wire pair 18, the twisted wire pair 18 being connected to each electronic board 14 by a respective coupling 20. The length of the twisted wire pair 18 between successive electronic boards 14 is substantially the same, and each electronic board 14 has a resistor 22 of a common known resistance mounted thereon.

Each coupling 20 is open during normal use and is closed to connect the wires of the twisted wire pair 18 in response to sensing a predetermined event in relation to the respective battery cell 12. In this way, the central processor 16 is able to determine from a level of voltage returned through the twisted wire pair 18 the number of battery cells 12 at which the predetermined event has been sensed.

In the example shown in the drawings, each coupling 20 is in the form of a photo-coupler, and each board 14 has a microprocessor 24 for monitoring the respective battery cell 12. Each microprocessor 24 is adapted to operate such that, if a predetermined event occurs, the microprocessor 24 switches on the photo-coupler to connect the wires of the twisted wire pair 18 to allow a current to pass back to the central processor 16.

The central processor 16 determines the number of battery cells 12 at which the predetermined event has been sensed by multiplying current along the twisted wire pair 18 by a resistance associated with each battery cell 12, and by dividing that product by the voltage drop along the twisted wire pair 18. The number of battery cells 12 affected is able to be calculated in this way as the resistance associated with each battery cell 12 is the same.

The twisted wire pair 18 may be in a series of discrete lengths, each length being connected between a respective pair of successive electronic boards 14. Alternatively, the twisted wire pair 18 may be in a single length linking together all of the electronic boards 14.

The predetermined event may be a failure of a battery cell, or some other event depending on the type of sensor used.

In one form, a dual wire configuration is used to connect each BMS board 14 in the series. The dual wire BMS utilises pre manufactured twisted pair of copper wires of similar length for consistency. Unlike the single wire BMS there is no permanently closed loop. Two unconnected twisted paired wires run from the main control box housing the central processor 16 and are connected separately to each BMS board 14 by a polarised two pin plug and header arrangement connected to a normally open photo-coupler 20.

A microprocessor chip 24 on each BMS board 14 monitors the cell 12. If a predetermined event occurs, the microprocessor 24 switches on the photo-coupler 20. A current is then allowed to pass between one wire in the twisted pair 18 to the other back to the main control box 16.

In another form, the connection of the twisted pair 18 to each BMS board 14 includes a fixed value resistor 22—typically 22 k ohms. In this configuration, when the photo-coupler 20 closes the circuit to the main control box 16 there is a discernable drop in the resistance in the circuit. This innovation allows for both the detection of and recording of the number of cells 12 affected at any one time. This is achieved by the central processor 16 subtracting the difference in resistance in the circuit before and after an event and dividing the result by the known value of the resistor 22.

In other forms, the use of two parallel normally unconnected wires has the advantage of allowing the developer to insert resistors 22 and other technologies with a minimal of effort to improve the BMS 10. In addition, the use of microprocessors 24 on each board 14 means upgrading the logic, only requiring reprogramming of the chips.

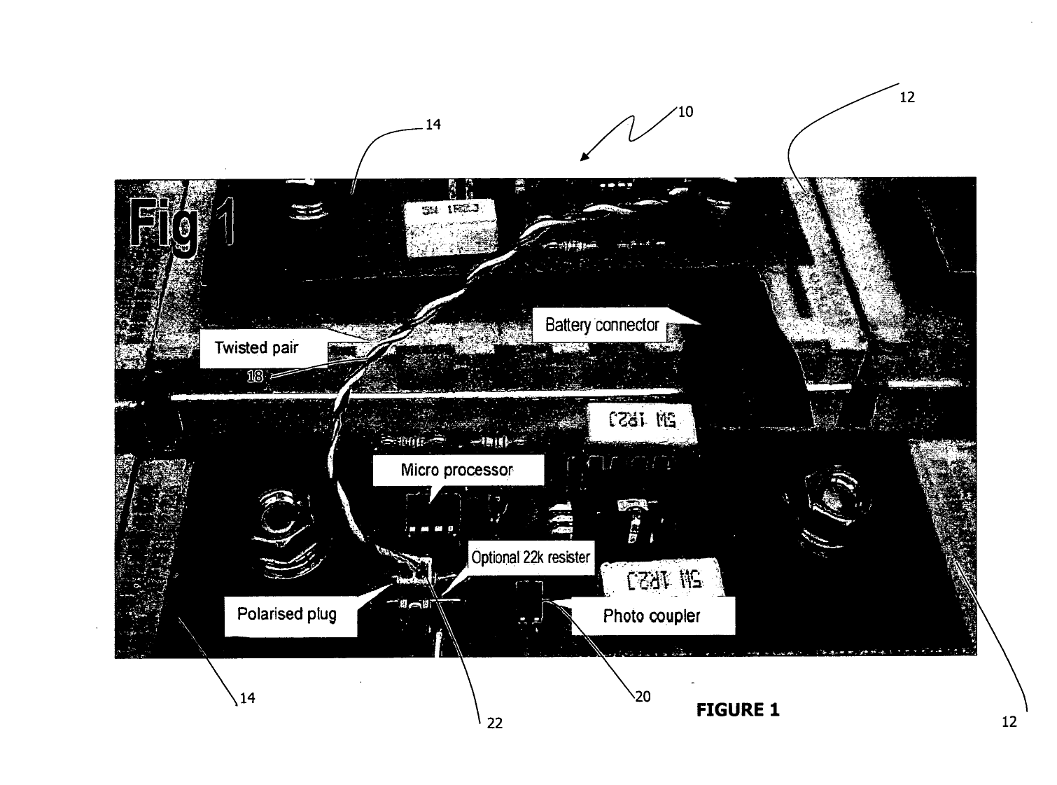

In FIG. 1, two unconnected wires 18, one coloured and one white, run between BMS boards 14. To ensure ease of installation and to ensure that the two wires 18 are never crossed unintentionally a polarised plug is utilised. To prevent electromagnetic pulse caused by the wires 18 oscillating near high current battery connectors only prefabricated twisted pair is used.

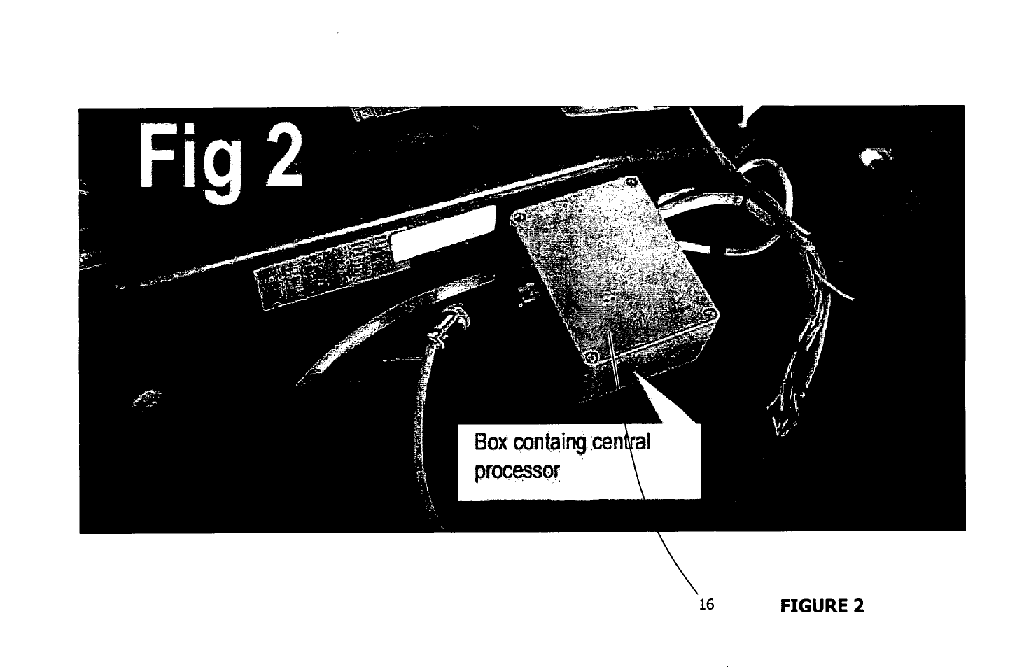

When the microprocessor 24 detects a predetermined event it turns on the normally open photo-coupler 20. This shorts the twisted pair 18 and allows a current to flow back to the central processor 16, see FIG. 2. When a 22 k resistor is installed at the indicated location the central processor 16 can calculate how many cells 12 have been affected by the event. This information can be stored for later retrieval and analysis. The length of the twisted pair 18 between BMS boards 14 is identical to help ensure for consistent resistance.

In alternative versions, other technologies can be inserted into the location indicated for the 22 k resistor 22. This is only possible because the invention uses a normally unconnected pair of wires 18 across the BMS boards 14.

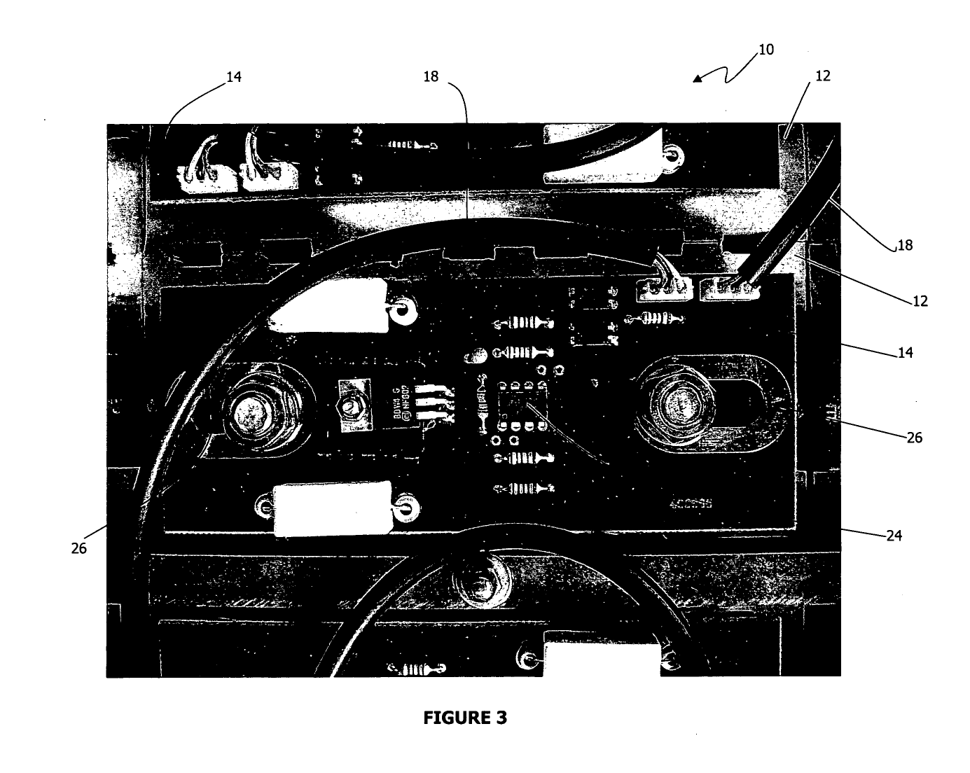

An electronic board 14 used in a battery management system in accordance with an alternative example is shown in FIG. 3. The electronic board 14 has similarities to the electronic board 14 shown in FIG. 1, and like features are referenced with like reference numerals. The electronic board 14 of FIG. 3 does notably differ in that slots 26 are provided to allow for variation in the distance between the terminals of the battery cell 12, such that the electronic board 14 is able to be used with a range of different battery cell models. The electrical connection between the board 14 and the battery cell 12 can be used in determining whether a predetermined event has occurred, for example by measuring the output of the battery cell 12. Also, the electronic board 14 of FIG. 3 differs in that separate like plugs, each at the end of a respective twisted wire 18, are used for connecting neighbouring battery cells.

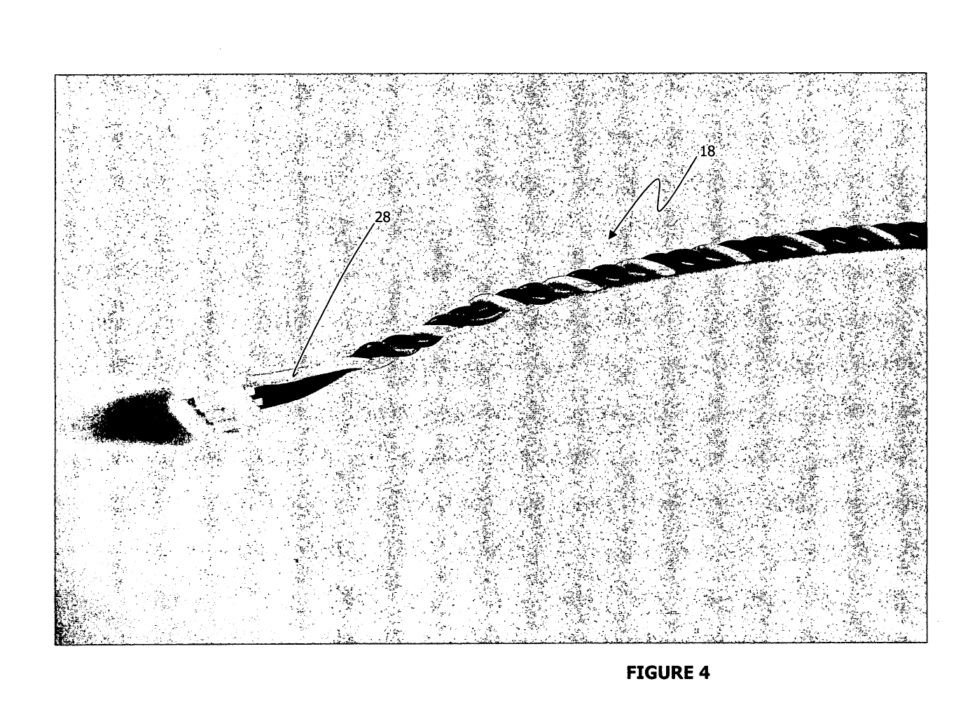

FIG. 4 shows a twisted wire pair 18 incorporating a third wire. The twisted wire pair 18 has a tight twist. The yellow wire 28 is new and is used for carrying data. The yellow wire is protected from EMF by being twisted in with the other signal wires.

In one example of the invention the 22 k resistor can be omitted. In this case the central processor instead uses the third wire (the yellow wire 28) to communicate to each board 14 individually to obtain information about the respective cell 12. The data on this wire is protected from EMF by being incorporated into the twisted pair.

While various embodiments of the present invention have been described above, it should be understood that they have been presented by way of example only, and not by way of limitation. It will be apparent to a person skilled in the relevant art that various changes in form and detail can be made therein without departing from the spirit and scope of the invention. Thus, the present invention should not be limited by any of the above described exemplary embodiments.

In one variation, a temperature sensor mounted on the board rests adjacent to the anode or the cathode of the battery cell to sense the temperature inside the battery cell. The temperature sensed by the temperature sensor may be used by the battery management system to determine whether a predetermined event has occurred in the form of the temperature within the battery cell being outside of a normal operating range.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

1. A battery management system for monitoring a plurality of battery cells, including a plurality of electronic boards, each of the electronic boards being mounted on a respective one of the battery cells, wherein the electronic boards are connected in series to a central processor by twisted wire pair, the twisted wire pair being connected to each electronic board by a coupling at each electronic board, wherein the coupling is open during normal use and is closed to connect the wires of the twisted wire pair in response to sensing a predetermined event in relation to the respective battery cell such that the central processor is able to determine from a level of voltage returned through the twisted wire pair the number of battery cells at which the predetermined event has been sensed.

2. A battery management system as claimed in claim 1, wherein each section of the twisted wire pair between successive electronic boards is substantially the same in length.

3. A battery management system as claimed in claim 1, wherein the coupling is a photo-coupler, and each board has a microprocessor for monitoring the respective battery cell, the microprocessor being adapted to operate such that, if a predetermined event occurs, the microprocessor switches on the photo-coupler to connect the wires of the twisted wire pair to allow a current to pass back to the central processor.

4. A battery management system as claimed in claim 1, wherein the twisted wire pair is prefabricated twisted wire pair.

5. A battery management system as claimed in claim 1, wherein the central processor determines the number of battery cells at which the predetermined event has been sensed by multiplying current along the twisted wire pair by a resistance associated with each battery cell, and by dividing that product by the voltage drop along the twisted wire pair.

6. A battery management system as claimed in claim 5, wherein each electronic board has a resistor of a known resistance mounted thereon.

7. A battery management system as claimed in claim 6, wherein each resistor has the same resistance.

8. A battery management system as claimed in claim 1, wherein the predetermined event sensed by the electronic board is a failure of the respective battery cell.

9. (canceled)
